(19) United States
(12) Patent Application Publication
(10) Pub. No.: US 2025/0160079 A1
(43) Pub. Date: May 15, 2025

(54) LIGHT SOURCE MODULE AND MANUFACTURING METHOD THEREOF

(71) Applicant: Lextar Electronics Corporation, Hsinchu City (TW)

(72) Inventors: Fu-Hsin CHEN, Hsinchu City (TW); Chun-Min LIN, Hsinchu City (TW)

(21) Appl. No.: 18/939,166

(22) Filed: Nov. 6, 2024

(30) Foreign Application Priority Data
Nov. 13, 2023 (TW) 112143610

(51) Int. Cl. H01L 33/60; H01L 33/50

(52) U.S. Cl. CPC H10H 20/856; H10H 20/8512; H10H 20/0361; H10H 20/0363

(57) ABSTRACT

A light source module is provided. The light source module includes a substrate, a light source and a packaging material. The light source is disposed on the substrate, wherein the light source comprises a top surface and a lateral surface. The packaging material is disposed on the substrate and covers the light source, wherein a recess is formed on the packaging material, and the recess corresponds to the top surface.

### CROSS REFERENCE TO RELATED DISCLOSURES

This application claims priority of Taiwan Patent Application No. 112143610, filed on Nov. 13, 2023, the entirety of which is incorporated by reference herein,

### Technical Field

The present disclosure relates to a light source module, and, in particular, to a light source module with light-emitting diodes.

### BACKGROUND

### Description of the Related Art

The light-emitting principle and structure of light-emitting diodes (LEDs) are different from those of traditional light sources. Light-emitting diodes (LEDs) have advantages including low power consumption, long component life, no warm-up time, and a fast response speed. In addition, the light-emitting diodes (LEDs) are small in size and have improved vibration-resistance, making them suitable for mass production. They can easily be made into extremely small or array-type components to meet the requirements of various applications. Light-emitting diodes (LEDs) are widely utilized in various consumer electronics products available on the market, such as optical display devices, laser diodes, traffic signals, data storage devices, communication devices, lighting devices, and medical devices.

In the conventional process of manufacturing light source modules (light-emitting diode light source modules), multiple light source modules need to be separated from each other through a cutting process. However, during the cutting process, water vapor may penetrate into the light source module, and the production yield of the light source modules is decreased.

### SUMMARY

An embodiment of the present disclosure provides a light source module. The light source module includes a substrate, a light source and a packaging material. The light source is disposed on the substrate, wherein the light source comprises a top surface and a lateral surface. The packaging material is disposed on the substrate and covers the light source, wherein a recess is formed on the packaging material, and the recess corresponds to the top surface.

Utilizing the light source module of the embodiment of the present disclosure, the reflective layer and the wavelength conversion material are protected by the packaging material. The reflective layer and the wavelength conversion material is prevented from being contaminated by water vapor penetration during the cutting process. The production yield of light source modules is improved. Additionally, based on the structure of the packaging material, the position of the reflective layer can be appropriately adjusted, and the light emission angle thus can be more easily controlled.

### BRIEF DESCRIPTION OF THE DRAWINGS

The present disclosure can be more fully understood by reading the subsequent detailed description and examples with references made to the accompanying drawings, wherein:

FIG. 1 shows a light source module of a first embodiment of the disclosure;

FIG. 2 shows a light source module of a second embodiment of the disclosure;

FIG. 3 shows a light source module of a third embodiment of the disclosure;

FIG. 4 shows a light source module of a fourth embodiment of the disclosure;

FIG. 5 is a flowchart of a method for manufacturing a light source module of the embodiment of the disclosure;

FIG. 6 shows a mold for imprinting of the embodiment of the disclosure;

FIG. 7 is a flowchart of a method for manufacturing a light source module of another embodiment of the disclosure;

FIG. 8 is a flowchart of a method for manufacturing a light source module of further another embodiment of the disclosure; and

FIGS. 9A, 9B and 9C are top-views of the light source module of the embodiment of the disclosure.

### DETAILED DESCRIPTION

The following description is made for the purpose of illustrating the general principles of the present disclosure and should not be taken in a limiting sense. The scope of the present disclosure is best determined by reference to the appended claims.

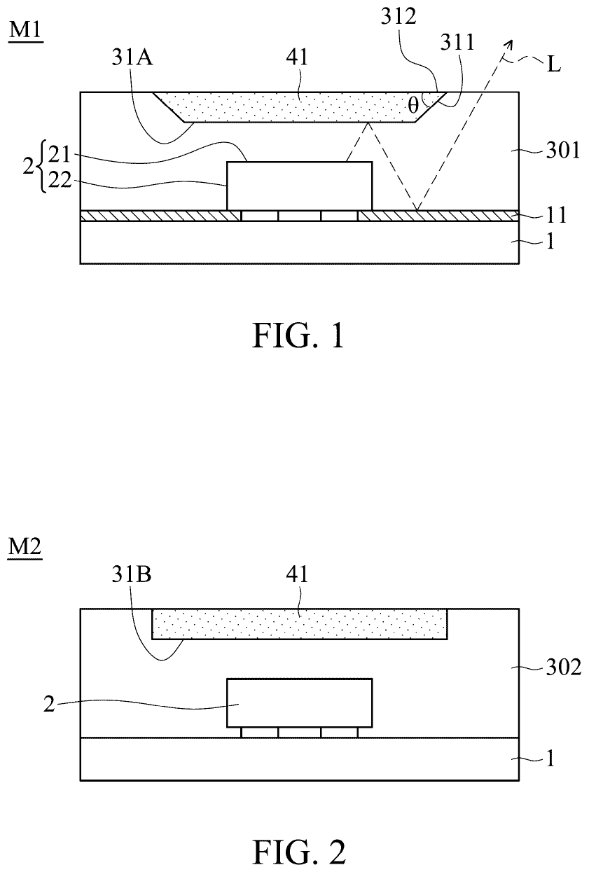

FIG. 1 shows the first embodiment of a light source module of the disclosure. With reference to FIG. 1, the light source module M1 of the first embodiment of the disclosure includes a substrate 1, a light source 2 and a packaging material 301. The light source 2 is disposed on the substrate 1. The light source 2 comprises a top surface 21 and a lateral surface 22. The packaging material 301 is disposed on the substrate 1 and covers the light source 2. A recess 31A is formed on the packaging material 301, and the recess 31A corresponds to the top surface 21.

With reference to FIG. 1, in one embodiment, the light source module M1 further includes a reflective layer 41. The reflective layer 41 fills the recess 31A. A portion of the light L from the light source 2 is reflected by the reflective layer 41, and the emitting angle of the light L is modified. In one embodiment, a reflective layer 11 is formed on the surface of the substrate 1. The disclosure is not meant to restrict the present disclosure.

In one embodiment, based on the arrangement of the reflective layer 41 and the recess 31A, the central light emission amount of the light source module M1 can be reduced, and the peripheral light emission amount thereof can be increased.

With reference to FIG. 1, in one embodiment, the depth of the recess 31A is between 50 μm˜20 μm. The cross-section of the recess 31A is trapezoidal. An included angle θ is formed between the lateral side 311 of the cross-section and the bottom side 312 of the cross-section, and the included angle θ is between 10 degrees˜80 degrees. The disclosure is not meant to restrict the present disclosure. For example, the value of the included angle θ can be modified if required.

As the embodiment of FIG. 1 shows, the cross-section of the recess is trapezoidal. Above disclosure is not meant to restrict the present disclosure. In other embodiment, the shape of the cross-section of the recess can be modified. FIG. 2 shows a light source module of a second embodiment of the disclosure. With reference to FIG. 2, the light source module M2 of the second embodiment of the disclosure includes a packaging material 302. A recess 31B is formed on the packaging material 302. In this embodiment, the cross section of the recess 31B is rectangular. The reflective layer 41 fills the recess 31B.

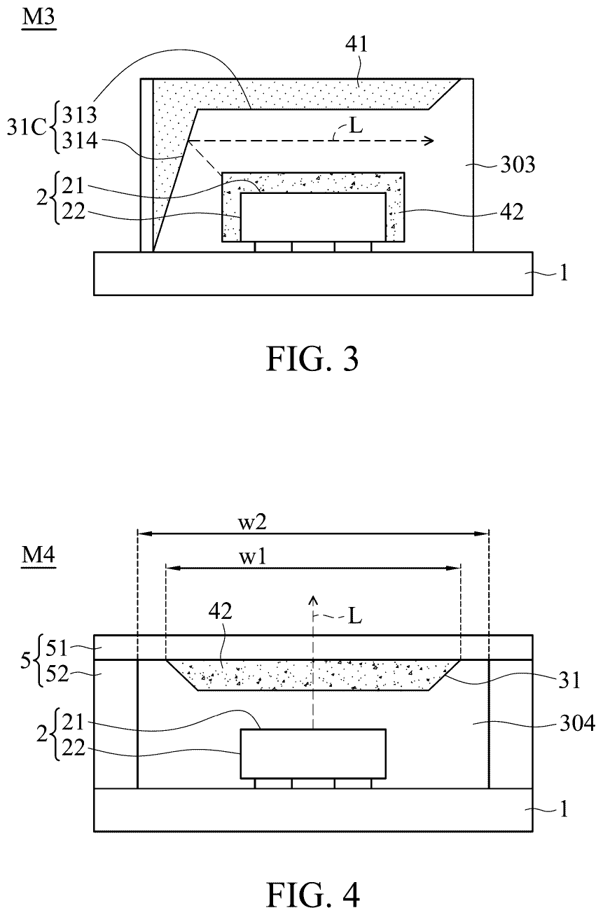

FIG. 3 shows a light source module of a third embodiment of the disclosure. With reference to FIG. 3, the light source module M3 of the third embodiment of the disclosure includes a substrate 1, a light source 2 and a packaging material 303. The light source 2 is disposed on the substrate 1. The light source 2 comprises a top surface 21 and a lateral surface 22. The packaging material 303 is disposed on the substrate 1 and covers the light source 2. A recess 31C is formed on the packaging material 303, and the recess 31C corresponds to the top surface 21 and a portion of the lateral surface 22. In one embodiment, the light source module M3 further includes a reflective layer 41. The reflective layer 41 fills the recess 31C. A portion of the light L from the light source 2 is reflected by the reflective layer 41, and the emitting angle of the light L is modified.

With reference to FIG. 3, in one embodiment, a wavelength conversion material 42 covers the light source 2. The wavelength conversion material 42 comprises quantum dot material, sulfide or phosphor. The light L provided by the light source 2 is converted by the wavelength conversion material 42. The color of the light L is modified.

With reference to FIG. 3, in one embodiment, the recess 31C includes a first section 313 and a second section 314. The first section 313 corresponds to the top surface 21. The second section corresponds to the lateral surface 22. The reflective layer 41 fills the first section 313 and the second section 314. The reflective layer 41 in the first section 313 and the second section 314 reflects the light L of the light source 2 to the lateral side. The light source module M3 is therefore a sideview packaging structure.

FIG. 4 shows a light source module of a fourth embodiment of the disclosure. With reference to FIG. 4, the light source module M4 of the fourth embodiment of the disclosure includes a substrate 1, a light source 2 and a packaging material 304. The light source 2 is disposed on the substrate 1. The light source 2 comprises a top surface 21 and a lateral surface 22. The packaging material 304 is disposed on the substrate 1 and covers the light source 2. A recess 31 is formed on the packaging material 304, and the recess 31 corresponds to the top surface 21. In one embodiment, the light source module M4 includes a wavelength conversion material 42. The wavelength conversion material 42 fills the recess 31. The wavelength conversion material 42 comprises quantum dot material, sulfide or phosphor. The light L provided by the light source 2 is converted by the wavelength conversion material 42. For example, the color of the light L is modified.

With reference to FIG. 4, the maximum width w1 of the recess 31 is smaller than the maximum width w2 of the packaging material 304.

With reference to FIG. 4, in one embodiment, the light source module M4 further comprises a waterproof material 5. The waterproof material 5 covers the packaging material 304. In one embodiment, the water vapor transmission rate (WVTR) of the waterproof material 5 is lower than 10⁻³ g/m2/day. The waterproof material 5 is utilized to stop water. In one embodiment, the waterproof material 5 includes glass (SiO₂).

With reference to FIG. 4, in one embodiment, the waterproof material 5 comprises a transparent portion 51 and a reflective portion 52. The transparent portion 51 covers the wavelength conversion material 42, and the reflective portion 52 surrounds the sides of the packaging material 304.

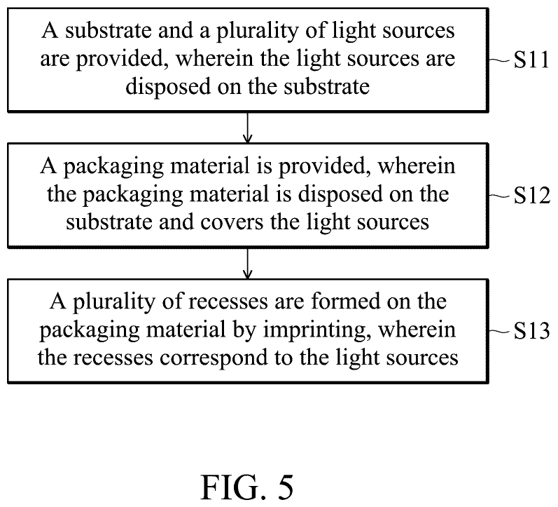

FIG. 5 is a flowchart of a method for manufacturing a light source module of the embodiment of the disclosure. With reference to FIG. 5, the method for manufacturing a light source module of the embodiment of the disclosure includes the following steps. First, a substrate and a plurality of light sources are provided, wherein the light sources are disposed on the substrate (S11). Next, a packaging material is provided, wherein the packaging material is disposed on the substrate and covers the light sources (S12). Then, a plurality of recesses are formed on the packaging material by imprinting, wherein the recesses correspond to the light sources (S13).

In one embodiment, in the imprinting process, the packaging material is in a non-fully solidified state (B-stage). The recesses are therefore can be formed on the packaging material by imprinting.

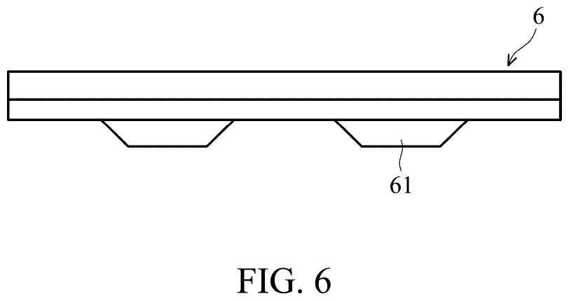

FIG. 6 shows a mold for imprinting of the embodiment of the disclosure. With reference to FIGS. 1 and 6, in one embodiment, the recesses 31A are imprinted by a mold 6. The hardness of the mold 6 is greater than the hardness of the packaging material 301 when the packaging material 301 is imprinted. The mold 6 includes a plurality of protrusions 61, and the protrusions 61 are utilized to from the recesses 31A.

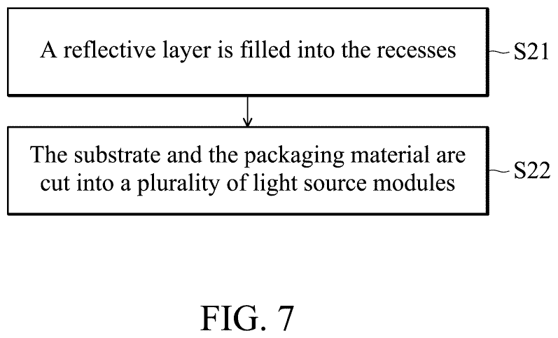

FIG. 7 is a flowchart of a method for manufacturing a light source module of another embodiment of the disclosure. With reference to FIGS. 1, 2, 3 and 7, the method for manufacturing a light source module of the embodiment of the disclosure further includes the following steps. First, a reflective layer is filled into the recesses (S21). Then, the substrate and the packaging material are cut into a plurality of light source modules (S22). Utilizing the method as shown in FIGS. 5 and 7, the light source module of the first, second and third embodiments are achieved.

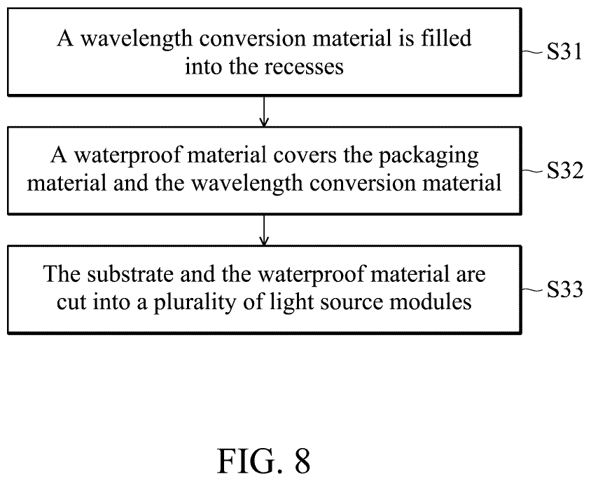

FIG. 8 is a flowchart of a method for manufacturing a light source module of further another embodiment of the disclosure. With reference to FIGS. 4 and 8, the method for manufacturing a light source module of the embodiment of the disclosure further includes the following steps. First, a wavelength conversion material is filled into the recesses (S31). Then, a waterproof material covers the packaging material and the wavelength conversion material (S32). Next, the substrate and the waterproof material are cut into a plurality of light source modules (S33). Utilizing the method as shown in FIGS. 5 and 8, the light source module of the fourth embodiment is achieved.

In one embodiment, the cut light source module has a single package structure. In one embodiment, the cut light source module belongs to a Near Chip Scale Package (NCSP), which is a cavity-free structure.

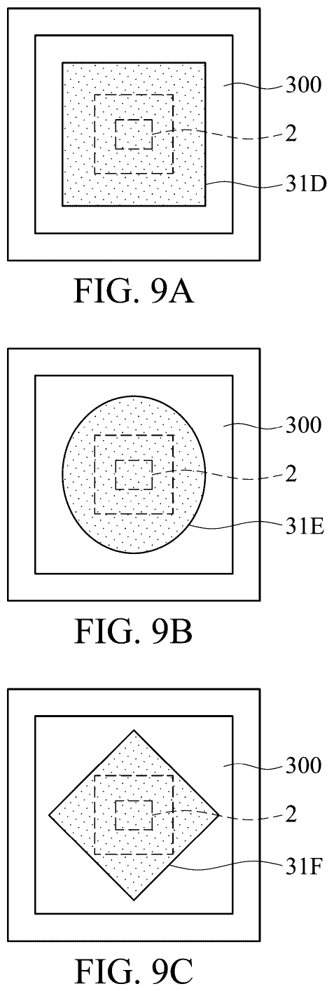

FIGS. 9A, 9B and 9C are top-views of the light source module of the embodiment of the disclosure. With reference to FIGS. 9A, 9B and 9C, in the embodiment of the disclosure, the shape of the recess can be modified. For example, in FIG. 9A, the recess 31D is formed on the packaging material 300, and the recess 31D is rectangular. In FIG. 9B, the recess 31E is formed on the packaging material 300, and the recess 31E is circular. In FIG. 9C, the recess 31F is formed on the packaging material 300, and the recess 31F is diamond shaped. Through the shape change of the above-mentioned recesses, the designer can conveniently adjust the light emission angle. The disclosure is not meant to restrict the present disclosure.

The light source module of the embodiment of the present disclosure can be applied to large light-angle packaged light source module components, such as automotive backlights, TV backlights, and display backlights, where a large light-angle is required. The light-angle is defined as between 150 degrees ˜170 degrees. In one embodiment, the light source module may include blue light sources, a wavelength conversion material, and an optical film. In one embodiment, the light source module may include white light sources and an optical film.

In one embodiment, when the above-mentioned light source is a chip scale package (CSP), the light source is suitable for a structure in which the reflective material fills the recess.

In one embodiment, when the above-mentioned light source is a blue light chip, the light source is suitable for a structure in which the reflective material fills the recess. Moreover, the blue light chip is also suitable for a structure in which the wavelength conversion material fills the recess. The wavelength conversion materials include quantum dot materials, sulfides or phosphors.

Utilizing the light source module of the embodiment of the present disclosure, the reflective layer and the wavelength conversion material are protected by the packaging material. The reflective layer and the wavelength conversion material is prevented from being contaminated by water vapor penetration during the cutting process. The production yield of light source modules is improved. Additionally, based on the structure of the packaging material, the position of the reflective layer can be appropriately adjusted, and the light emission angle thus can be more easily controlled.

While the present disclosure has been described by way of example and in terms of the preferred embodiments, it should be understood that the present disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for manufacturing a light source module, comprising:
providing a substrate and a plurality of light sources, wherein the light sources are disposed on the substrate;
providing a packaging material, wherein the packaging material is disposed on the substrate and covers the light sources; and
forming a plurality of recesses on the packaging material by imprinting, wherein the recesses correspond to the light sources.

2. The method as claimed in claim 1, wherein in the imprinting process, the packaging material is in a non-fully solidified state (B-stage).

3. The method as claimed in claim 1, wherein the recesses are imprinted by a mold, and the hardness of the mold is greater than the hardness of the packaging material when the packaging material is imprinted.

4. A light source module, comprising:
a substrate;
a light source, disposed on the substrate, wherein the light source comprises a top surface and a lateral surface; and
a packaging material, disposed on the substrate and covering the light source, wherein a recess is formed on the packaging material, and the recess corresponds to the top surface.

5. The light source module as claimed in claim 4, wherein the light source comprises a chip scale package.

6. The light source module as claimed in claim 4, wherein the light source comprises a blue light chip.

7. The light source module as claimed in claim 5, further comprising a reflective layer, wherein the reflective layer fills the recess.

8. The light source module as claimed in claim 6, further comprising a wavelength conversion material, wherein the wavelength conversion material fills the recess, and the wavelength conversion material comprises quantum dot material, sulfide or phosphor.

9. The light source module as claimed in claim 8, further comprising a waterproof material, wherein the waterproof material covers the packaging material.

10. The light source module as claimed in claim 9, wherein the waterproof material comprises a transparent portion and a reflective portion, the transparent portion covers the wavelength conversion material, and the reflective portion surrounds the sides of the packaging material.
